(19) United States
(12) Patent Application Publication
(10) Pub. No.: US 2009/0068842 A1
(43) Pub. Date: Mar. 12, 2009

(54) METHOD FOR FORMING MICROPATTERNS IN SEMICONDUCTOR DEVICE

(75) Inventor: Won-Kyu KIM, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/164,012

(22) Filed: Jun. 28, 2008

(30) Foreign Application Priority Data
Sep. 12, 2007 (KR) 10-2007-0092643

(51) Int. Cl. H01L 21/308

(52) U.S. Cl. 438/694; 257/E21.235

(57) ABSTRACT

A method for forming a semiconductor device includes forming an etch target layer over a substrate, forming a first etch stop layer over the etch target layer, forming a second etch stop layer over the first etch stop layer, forming a first sacrificial layer over the second etch stop layer, forming first sacrificial patterns by selectively etching the first sacrificial layer, forming second sacrificial layer over the second etch stop layer and the first sacrificial patterns, etching the second sacrificial layer and the second etch stop layer until the first sacrificial patterns are exposed and the second sacrificial layer remain only on sidewalls of the first sacrificial patterns, removing the exposed first sacrificial patterns, etching the exposed second etch stop layer mask to define a plurality of first structures, etching the first etch stop layer, and etching the etch target layer.

### CROSS-REFERENCE TO RELATED APPLICATIONS

The present invention claims priority of Korean patent application number 2007-0092643, filed on Sep. 12, 2007, which is incorporated by reference in its entirety.

### BACKGROUND OF THE INVENTION

The present invention relates to a method for fabricating a semiconductor device, and more particularly, to a method for forming a micropatterns in a semiconductor device.

Recently, as semiconductors become highly integrated, a line and space (LS) under 40 nm is needed. However, a typical photo-exposure equipment cannot form a LS under 60 nm. Accordingly, a double patterning technology (DPT) is introduced to attain a micro LS under 60 nm using the typical photo-exposure equipment.

FIGS. 1A to 1D are cross-sectional views illustrating a method for forming typical micropatterns through a DPT process.

Referring to FIG. 1A, an etch target layer 101 is formed over a substrate 100. First and second hard masks 102, 103, are sequentially formed over a resultant structure.

A photoresist layer is formed over the second hard mask 103. A mask process including a photo-exposure and development process is performed thereon using a photo mask to form first photoresist patterns 104.

Referring to FIG. 1B, an etch process is performed on the second hard mask 103 using the first photoresist patterns 104. Thus, second hard mask patterns 103A are formed.

A photoresist layer is formed over the first hard mask 102 and second hard mask patterns 103A.

Referring to FIG. 1C, a mask process is performed to form second photoresist patterns 105 between the second hard masks 103A.

Referring to FIG. 1D, the first hard mask 102 is etched using the second mask patterns 103A and second photoresist patterns 102A as an etch mask. Thus, first hard mask patterns 102A are formed.

The etch target layer 101 is etched using the hard mask patterns 102A as an etch mask. Thus, line type micropatterns are formed.

As described, in the typical method, a linewidth uniformity of the micropatterns is dependent on the overlay accuracy of the first and second masks. To secure the linewidth uniformity, the first and second masks are aligned with a linewidth of less than 4 nm based on ‘I Mean I+3σ’. Since the typical photo-exposure equipment controls the 3σ to be under 7 nm, new equipment will need to be developed. However, it is difficult to embody this equipment because of a technical limitation. Furthermore, as shown in FIG. 1C, a second mask process is performed on a resultant structure including the second hard mask patterns 103A to form the second photoresist patterns 105. Thus, the second hard mask patterns 103A may be damaged, changing a critical dimension of the second hard mask patterns 103A.

### SUMMARY OF THE INVENTION

Embodiments of the present invention relate to a method for forming micropatterns in a semiconductor device. This invention can improve a critical dimension of a linewidth uniformity by eliminating one of the two mask processes performed during a DPT process.

In accordance with an aspect of the present invention, there is provided a method for forming a semiconductor device. The method includes forming an etch target layer over a substrate, forming a first etch stop layer over the etch target layer, forming a second etch stop layer over the first etch stop layer, forming a first sacrificial layer over the second etch stop layer, forming first sacrificial patterns by selectively etching the first sacrificial layer, forming second sacrificial layer over the second etch stop layer and the first sacrificial patterns, the second sacrificial layer being conformal to the first sacrificial patterns, etching the second sacrificial layer and the second etch stop layer until the first sacrificial patterns are substantially exposed and the second sacrificial layer remain only on sidewalls of the first sacrificial patterns, the remaining second sacrificial layer defining second sacrificial patterns, removing the exposed first sacrificial patterns, the second sacrificial patterns defining openings that expose the second etch stop layer, etching the exposed second etch stop layer using the second sacrificial patterns as an etch mask to define a plurality of first structures, the first etch stop serving as an etch barrier layer while the exposed second etch stop layer is being etched, etching the first etch stop layer using the first structures as an etch mask to define a plurality of second structures, and etching the etch target layer by using the second structures as an etch mask.

### BRIEF DESCRIPTION OF THE DRAWINGS

FIGS. 1A to 1D are cross-sectional views illustrating a method for forming typical micropatterns through a DPT process.

FIGS. 2A to 2I are cross-sectional views describing a method for forming micropatterns in a semiconductor device in accordance with an embodiment of the present invention.

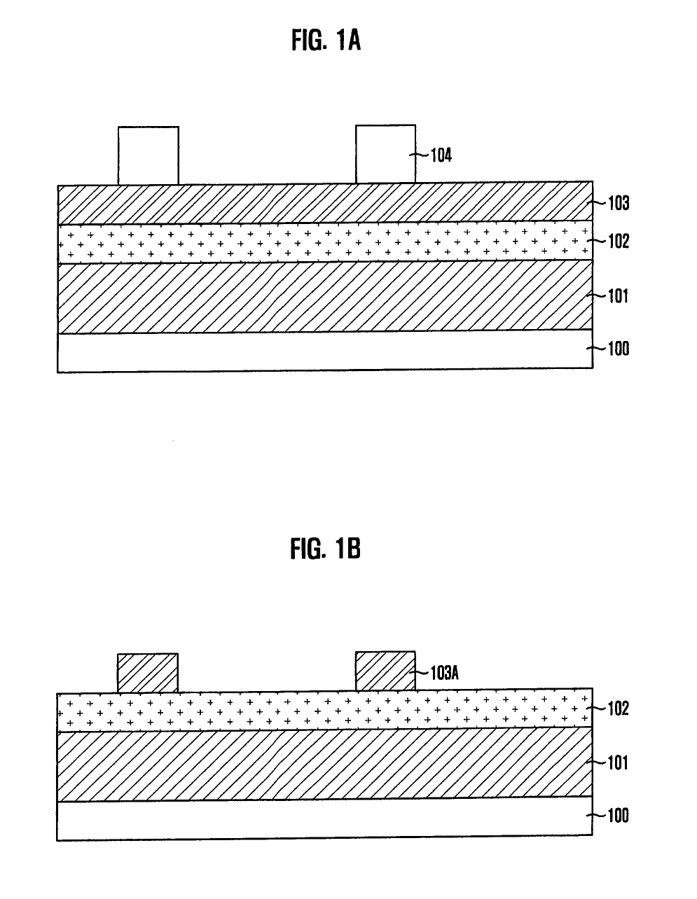

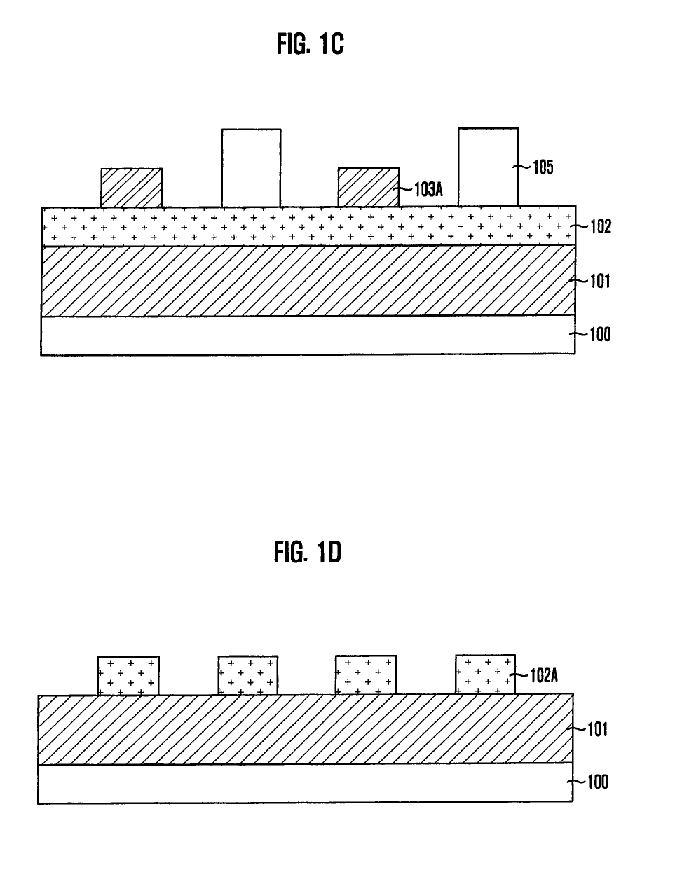

### DESCRIPTION OF SPECIFIC EMBODIMENTS

Embodiments of the present invention relate to a method for forming micropatterns in a semiconductor device. Referring to the drawings, the illustrated thickness of layers and regions are exaggerated to facilitate explanation. When a first layer is referred to as being “on” a second layer or “on” a substrate, it could mean that the first layer is formed directly on the second layer or the substrate, or it could also mean that a third layer may exist between the first layer and the substrate. Furthermore, the same or like reference numerals throughout the various embodiments of the present invention represent the same or like elements in different drawings.

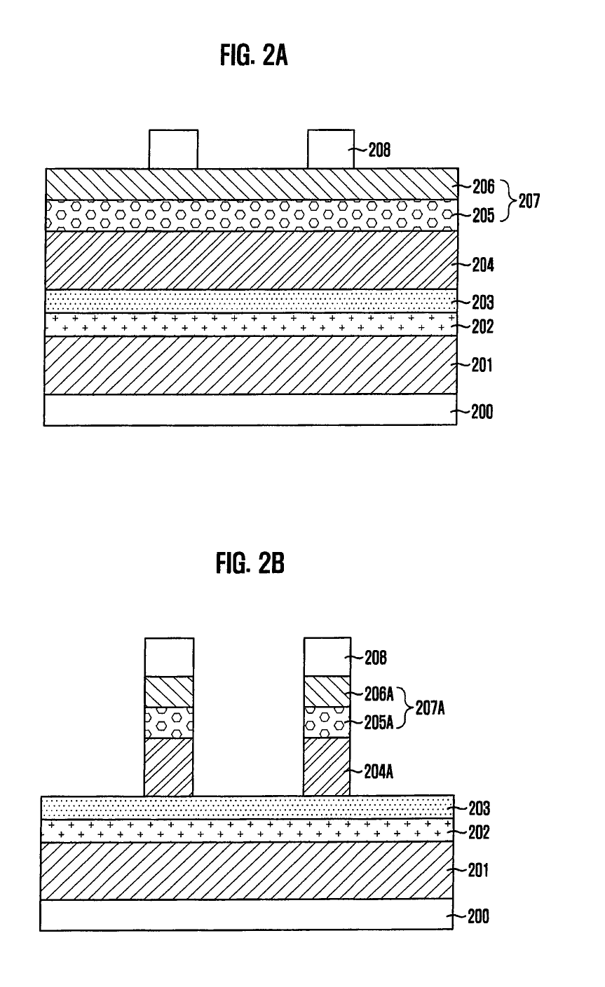

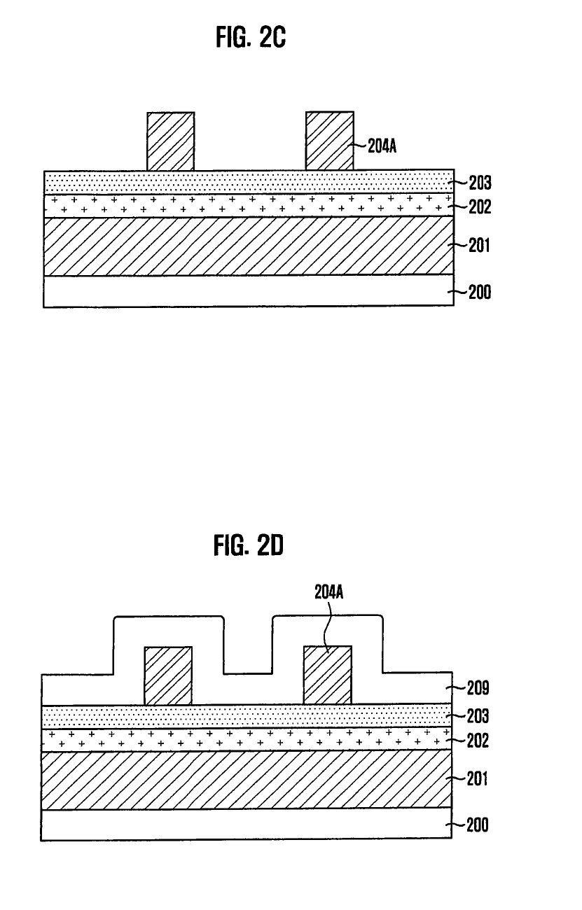

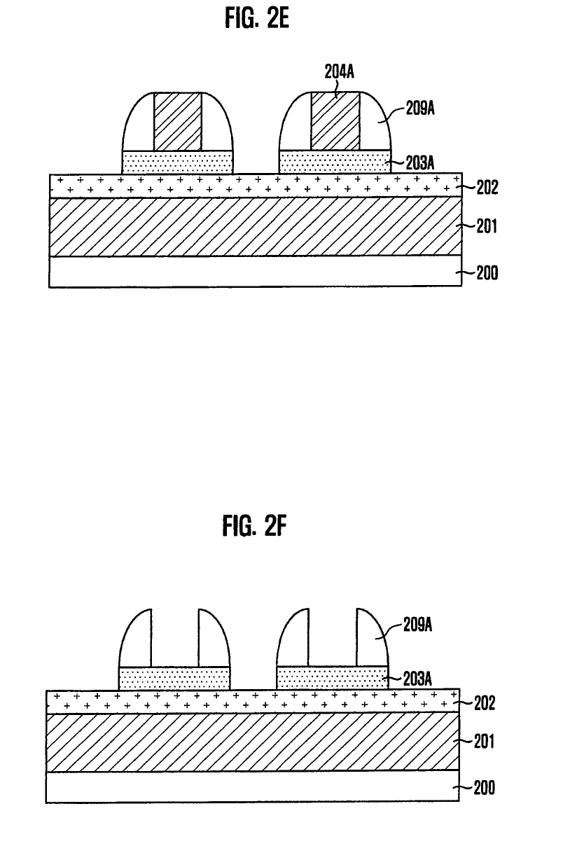

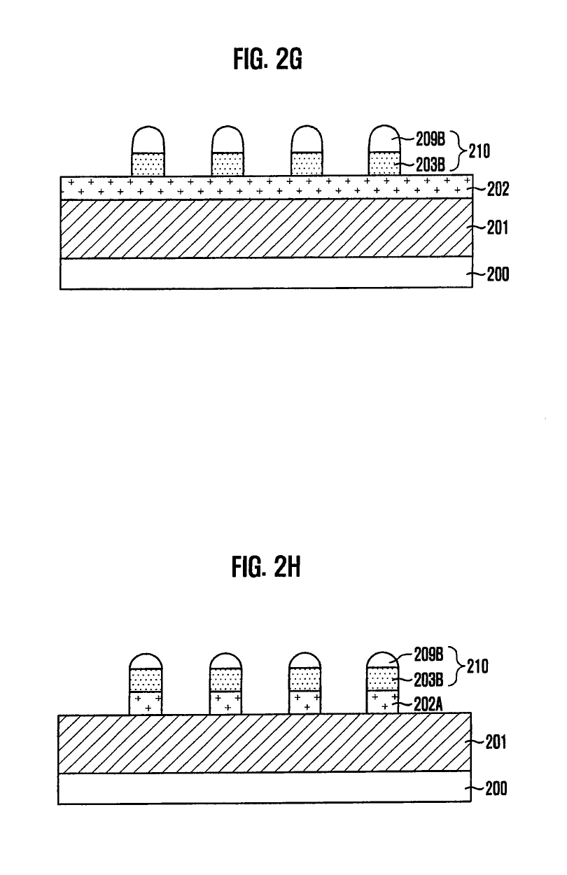

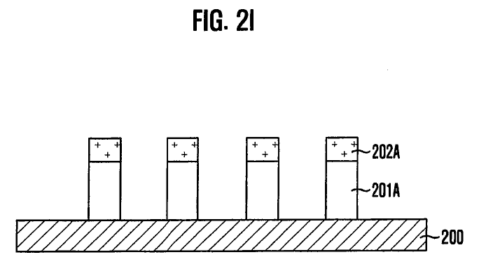

FIGS. 2A to 2I are cross-sectional views describing a method for forming micropatterns in a semiconductor device in accordance with an embodiment of the present invention. In this embodiment, a hard mask formed over a gate electrode is used as an etch target layer to form micropatterns in a semiconductor device.

Referring to FIG. 2A, a hard mask 201 functioning as an etch target layer is formed over a substrate 200. The hard mask may include one selected from a group consisting of an oxide layer, a nitride layer, an oxy-nitride layer, a carbon containing layer (e.g., an amorphous carbon layer) a polycrystalline silicon layer, and a stack structure thereof. For instance, the oxide layer may be a silicon oxide (SiO₂) layer and the nitride layer may be a silicon nitride (Si₃N₄) layer. The oxy-nitride layer may be a silicon oxy-nitride (SiON) layer.

A first etch stop layer 202 is formed over the hard mask 201. The first etch stop layer 202 may include a material having a high etch selectivity ratio with the hard mask 201. For instance, the first etch stop layer 202 may include one selected from a group consisting of an oxide layer (e.g., a SiO₂ layer), nitride layer (e.g., a Si₃N₄ layer), oxy-nitride layer (e.g., a SiON layer), and polycrystalline silicon layer (e.g., a doped or an un-doped polycrystalline silicon layer).

A second etch stop layer 203 is formed over the first etch stop layer 202. The second etch stop layer 203 may include a material having a high etch selectivity to the first etch stop layer 202. Particularly, the second etch stop layer 203 may include a material used in a subsequent second sacrificial layer 209 (refer to FIG. 2D). For instance, the second etch stop layer 203 may be one selected from a group consisting an oxide layer (e.g., a SiO₂ layer), nitride layer (e.g., a Si₃N₄ layer), oxy-nitride layer (e.g., a SiON layer), and polycrystalline silicon layer (e.g., a doped or an un-doped polycrystalline silicon layer). The second etch stop layer 203 is formed to have a thickness over 0 Å to approximately 500 Å. In one embodiment, the second etch stop layer 203 is formed to have a thickness of no more than approximately 100 Å.

A first sacrificial layer 204 is formed over the second etch stop layer 203. The first sacrificial layer 204 may include a material having an etch selectivity to the second etch stop layer 203. For instance, the first sacrificial layer 204 may include a material selected for its removal rate during a dry or wet etch process. Specifically, the first sacrificial layer 204 may include an oxide layer (e.g., a SiO₂ layer) or a spin coating layer which can be easily removed through the wet etch process or the polycrystalline silicon layer (or amorphous carbon layer) which can be easily removed through the dry etch process. The oxide layer may include a tetra ethyle ortho silicate (TEOS) layer or a high aspect ratio process (HARP) layer. The spin coating layer may include a spin on dielectric (SOD) layer or a spin on glass (AOG) layer. The first sacrificial layer 204 is formed with a sufficient thickness as not to be removed when the second etch stop layer 203 is etched. For instance, the first sacrificial layer 204 is formed to have a thickness of approximately 500 Å to approximately 2,000 Å.

A hard mask (not shown) is formed over the first sacrificial layer 204. This is because a pattern defect may be caused when the first sacrificial layer 204 is etched due to immersion photoresist patterns, particularly, a pattern deformation and a decrease in an etch selectivity ratio. Accordingly, the first sacrificial layer 204 may be additionally etched using the hard mask.

An anti-reflection layer 207 may be formed over the first sacrificial layer 204. Herein, the anti-reflection layer 207 may include a single layer of a bottom anti-reflective coating (BARC) layer or a multi layer of a dielectric anti-reflective coating (DARC) layer 205 and the BARC layer 206. For instance, the DARC layer 205 may include a material with a 1.95 refractive index and a 0.53 extinction coefficient. The BARC layer 206 may include an organic material.

Photoresist patterns 208 are formed over the anti-reflection layer 207. At this time, the photo-exposure process forming the photoresist patterns 208 are performed to have a LS ratio of approximately 1:3.

Referring to FIG. 2B, the anti-reflection layer 207 and first sacrificial patterns 204 are etched using the photoresist patterns 208. The etch process is performed using the second etch stop layer 203 as an etch barrier layer to expose the second etch stop layer 203. The etch process may be a dry etch process or a wet etch process.

Referring to FIG. 2C, the photoresist patterns 208 (refer to FIG. 2B) and anti-reflection patterns 207A (refer to FIG. 2B) are removed. The removal process may be an ashing process using an oxygen (O₂) plasma. A profile of the first sacrificial patterns 204A is not changed using this process.

Referring to FIG. 2D, a second sacrificial layer 209 is formed over the second etch stop layer 203 including the first sacrificial patterns 204A. The second sacrificial layer 209 is formed with a substantially uniform thickness along a resultant structure including the first sacrificial patterns 204A. A substantially uniform thickness should be maintained along the sidewall of the first sacrificial patterns 204A as this will become the final mask pattern. To maintain the vertical profile along the sidewalls, the second sacrificial layer 209 includes a material with a fine characteristic, i.e., a step coverage rate of more than approximately 0.9. Here, the step coverage rate indicates a degree of uniformity of a deposited material. That is, the step coverage rate indicates a ratio of a first thickness T1 (e.g., a material deposited on the first etch stop layer 203) to a second thickness T2 (e.g., a material deposited on the sidewalls of the first sacrificial patterns 204A). Thus, the step coverage rate of more than approximately 0.9 indicates that a ratio of the second thickness T2 to the first thickness T1 is approximately 0.9:1.

Likewise, to acquire a step coverage of more than approximately 0.9, the second sacrificial layer 209 can be formed through an atomic layer dielectric (ALD) process. Also, the second sacrificial layer 209 may include a material used in the second etch stop layer 203 or a material having a similar etch rate with the second etch stop layer 203. An etch ratio of the second sacrificial layer 209 to the second etch stop layer 203 may be approximately 1:1.

Referring to FIG. 2E, an anisotropic etch process is performed to expose the first etch stop layer 202. The anisotropic etch process (vertical direction) removes the second sacrificial layer 209 on top of the first sacrificial patterns 204A and on top of the second etch stop layer 203. However the sacrificial layer 209 on the sidewall of the first sacrificial patterns 204A has enough material in the vertical direction that not all it is removed during the etching. This allows the sacrificial layer 209 on the sidewall of the first sacrificial patterns 204A and the first sacrificial patterns 204A to act as a mask when etching the second etch stop layer 203. The etched second sacrificial layer 209 and second etch stop layer 203 are formed into second sacrificial patterns 209A and second etch stop patterns 203A, respectively. The etch process may be an anisotropic dry etch process (e.g., an etch-back process) in a plasma etch apparatus.

Referring to FIG. 2F, the first sacrificial patterns 204A (refer to FIG. 2E) are selectively removed. The removal process may be a wet etch process or a dry etch process using the second sacrificial patterns 209A and second etch stop patterns 203A as an etch barrier layer. For instance, when the first sacrificial patterns 204A include the oxide layer, diluted hydrogen fluoride (DHF) including HF and deionized water (DIW) at a ratio of approximately 50:1 to approximately 100:1 or a buffered oxide etchant (BOE) including NH₄F and HF at a ratio of approximately 20:1 to approximately 300:1 may be used to perform the wet etch process. When the first sacrificial patterns 204A include the amorphous carbon layer, nitrogen (N₂) and O₂ may be used to perform the dry etch process. When the first sacrificial patterns 204A include the polycrystalline silicon layer, the HBr gas may be used to perform the dry etc process.

Referring to FIG. 2G, the second stop patterns 203A is selectively etched using the second sacrificial patterns 209A as a mask and the first etch stop layer 202 as an etch barrier layer. The etch process may be the anisotropic dry etch process (e.g. an etch-back process) in the plasma etch apparatus. Thus, remaining patterns 210 are formed over the first etch stop layer 202. The remaining patterns 210 include remaining second sacrificial patterns 209B and remaining second etch stop patterns 203B.

Even though the second sacrificial patterns 209A are formed in an ox-horn shape after the etch process shown in FIG. 2E, the ox-horn-type second sacrificial patterns 209A are removed through the etch-back process shown in FIG. 2G. Thus, the remaining patterns 210 are formed to have a profile shown in FIG. 2G.

Referring to FIG. 2H, the first etch stop layer 202 are etched using remaining patterns 210 as an etch barrier layer. The etch process may be a wet etch process or a dry etch process. The dry etch process is preferably performed. Herein, the etched first etch stop layer 202 is called first etch stop patterns 202A.

Referring to FIG. 2I, the hard mask 201 is etched using the remaining patterns 210 and first etch stop patterns 202A as an etch barrier layer. Hard mask patterns 201A (or target patterns) are obtained. The hard mask patterns are then used to etch the substrate 200. The etch process may be the wet etch process or the dry etch process. The dry etch process is preferably performed. Thus a hard mask micropattern with a LS ratio of 1:3 is formed.

In this invention, micropatterns of a quality which can be formed through a DPT process are formed through just one mask process. Also, a critical dimension for the uniformity of a linewidth, increased by a misalignment during a typical DPT process, can be improved.

While the present invention has been described with respect to the specific embodiments, the above embodiments of the present invention are illustrative and not limitative. In this invention, the hard mask is used as an etch target layer. However, the etch target layer can be any other materials, e.g., a conductive layer, used for the semiconductor device. It will be apparent to those skilled in the art that various changes and modifications may be made without departing from the spirit and scope of the invention as defined in the following claims.

What is claimed is:

1. A method for forming a semiconductor device, the method comprising:
forming an etch target layer over a substrate;
forming a first etch stop layer over the etch target layer;
forming a second etch stop layer over the first etch stop layer;
forming a first sacrificial layer over the second etch stop layer;
forming first sacrificial patterns by selectively etching the first sacrificial layer;
forming second sacrificial layer over the second etch stop layer and the first sacrificial patterns, the second sacrificial layer being conformal to the first sacrificial patterns;
etching the second sacrificial layer and the second etch stop layer until the first sacrificial patterns are substantially exposed and the second sacrificial layer remain only on sidewalls of the first sacrificial patterns, the remaining second sacrificial layer defining second sacrificial patterns;
removing the exposed first sacrificial patterns, the second sacrificial patterns defining openings that expose the second etch stop layer;
etching the exposed second etch stop layer using the second sacrificial patterns as an etch mask to define a plurality of first structures, the first etch stop serving as an etch barrier layer while the exposed second etch stop layer is being etched;
etching the first etch stop layer using the first structures as an etch mask to define a plurality of second structures; and
etching the etch target layer by using the second structures as an etch mask.

2. The method of claim 1, wherein the second etch stop layer and the second sacrificial layer include different materials.

3. The method of claim 1, wherein the second etch stop layer and the second sacrificial layer include materials that have substantially the same etch rate.

4. The method of claim 1, wherein the second sacrificial layer has significantly different etch characteristics from the first sacrificial layer.

5. The method of claim 4, wherein the second etch stop layer has significantly different etch characteristics from the first etch stop layer.

6. The method of claim 5, wherein the first sacrificial layer includes one selected from a group consisting of an oxide layer, a spine coating layer, a polycrystalline silicon layer, and an amorphous carbon layer.

7. The method of claim 1, further comprising:
forming an anti-reflection layer over the first sacrificial layer.

8. The method of claim 7, wherein the anti-reflection layer includes a bottom anti-reflective coating (BARC) layer.

9. The method of claim 8, wherein the anti-reflection layer has a stack structure of a dielectric anti-reflective coating (DARC) layer and the BARC layer.

10. The method of claim 1, wherein removing the first sacrificial patterns is performed through a dry etch process or a wet etch process.

11. The method of claim 10, wherein the dry etch process is performed using nitrogen (N₂) and oxygen (O₂) gases or hydrogen bromide (HBr) gas, or a combination thereof.

12. The method of claim 10, wherein the wet etch process is performed using a diluted hydrogen fluoride (DHF) or buffered oxide etchant (BOE).

13. The method of claim 1, wherein the first structures include the second sacrificial patterns and the second etch stop layer.

14. The method of claim 13, wherein the second structures include the second sacrificial patterns, the second etch stop layer, and the first etch stop layer.

15. The method of claim 1, wherein the etch target layer is etched to form target patterns.

16. The method of claim 1, wherein the etch target layer is one selected from a group consisting of an oxide layer, a nitride layer, an oxy-nitride layer, an amorphous layer, a polycrystalline silicon layer, and a stack structure thereof.
